(19) United States
(12) Patent Application Publication
(10) Pub. No.: US 2019/0013204 A1
(43) Pub. Date: Jan. 10, 2019

(54) METHOD OF FABRICATING BURIED WORD LINE AND GATE ON FINFET

(71) Applicants: UNITED MICROELECTRONICS CORP., Hsin-Chu City (TW); Fujian Jinhua Integrated Circuit Co., Ltd., Quanzhou City (CN)

(72) Inventors: Tien-Chen Chan, Tainan City (TW); Ger-Pin Lin, Tainan City (TW); Tsuo-Wen Lu, Kaohsiung City (TW); Chin-Wei Wu, Hsinchu City (TW); Yu-Chun Wang, Kaohsiung City (TW); Shu-Yen Chan, Changhua County (TW)

(21) Appl. No.: 15/659,653

(22) Filed: Jul. 26, 2017

(30) Foreign Application Priority Data
Jul. 4, 2017 (CN) 201710537348.8

(51) Int. Cl. H01L 21/28; H01L 29/66; H01L 21/3105; H01L 21/02; H01L 21/74; H01L 23/535; H01L 29/78

(52) U.S. Cl. CPC H01L 21/28229; H01L 29/66795; H01L 21/31051; H01L 21/02071; H01L 21/0206; H01L 21/02532; H01L 21/3065; H01L 21/02238; H01L 21/02164; H01L 21/743; H01L 23/535; H01L 29/7851; H01L 21/0262

(57) ABSTRACT

A method of fabricating a buried word line includes forming a trench in a substrate. Next, a deposition process is performed to form a silicon layer on a sidewall and a bottom at the inner side of the trench. After the deposition process, a gate dielectric layer is formed in the trench. Finally, a conductive layer is formed to fill in the trench.

### BACKGROUND OF THE INVENTION

### 1. Field of the Invention

The present invention relates to a method of preventing current leakage, and more particularly to a method of forming a silicon layer to cover a rough surface to prevent current leakage.

### 2. Description of the Prior Art

The semiconductor industry has been seeking higher integration and further size reduction of the semiconductor device. A conventional semiconductor fabrication method includes a slicing step, a chamfering step, a lapping step, an etching step, a single-side polishing step, and a cleaning step in fabricating a wafer for forming an electronic component.

However, during the etching step, the surface of a substrate is often damaged. For example, when forming a trench or a fin using the etching step, the surface of the substrate becomes rough after the etching step. The rough surface of the substrate will cause current leakage afterwards.

### SUMMARY OF THE INVENTION

In view of the above, the present invention provides an extra silicon layer to fill the rough surface and prevent current leakage.

According to a first preferred embodiment of the present invention, a method of fabricating a buried word line includes providing a substrate with a trench therein. Next, a deposition process is preformed to form a silicon layer on an inner sidewall and an inner bottom of the trench. After the deposition process, a gate dielectric layer is formed in the trench. Finally, a conductive layer is formed to fill in the trench.

A fabricating method of a gate on a fin structure includes the steps of providing a substrate. A fin structure extends from the substrate. A dummy gate structure crosses and contacts the fin structure. Then, the dummy gate structure is removed to expose the fin structure. Later, a deposition process is performed to form a silicon layer covering a sidewall and a top plane of the fin structure. After the deposition process, a gate dielectric layer is formed to cover the fin structure. Finally, a conductive layer is formed to cross the fin structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 6 depict a fabricating method of a buried word line according to a preferred embodiment of the present invention, wherein:

FIG. 1 depicts a stage of providing substrate with STIs and trenches;

FIG. 2 is a fabricating stage following FIG. 1;

FIG. 3 is a fabricating stage following FIG. 2;

FIG. 4 is a fabricating stage following FIG. 3;

FIG. 5 is a fabricating stage following FIG. 4; and

FIG. 6 is a fabricating stage following FIG. 5.

FIG. 7 to FIG. 10 depict a method of fabricating a gate on a fin structure according to a second preferred embodiment of the present invention, wherein:

FIG. 7 depicts a stage of providing substrate with a fin structure;

FIG. 8 is a fabricating stage following FIG. 7;

FIG. 9 is a fabricating stage following FIG. 8; and

FIG. 10 is a fabricating stage following FIG. 9.

### DETAILED DESCRIPTION

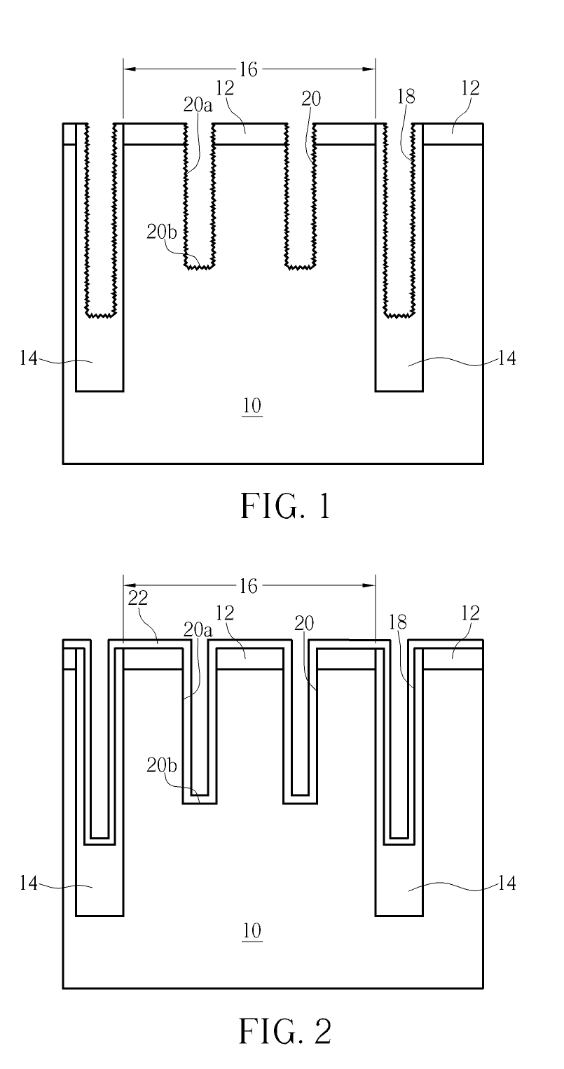

FIG. 1 to FIG. 6 depict a fabricating method of a buried word line according to a preferred embodiment of the present invention. As shown in FIG. 1, a substrate 10 is provided. A mask layer 12 covers the substrate 10. The mask layer 12 may include an oxide layer and a nitride layer. At least one shallow trench isolation (STI) 14 is disposed within the substrate 10 and the mask layer 12. The STI 14 defines an active region 16 on the substrate 10. Two STIs 14 are shown in the exemplary embodiments disclosed herein, however, there may be other numbers of STIs 14. The substrate 10 may be a silicon substrate, a germanium substrate, a gallium arsenide substrate, a silicon germanium substrate, an indium phosphide substrate, a gallium nitride substrate or a silicon carbide substrate. In this embodiment, the substrate 10 is a silicon substrate. Next, at least one trench is formed in the substrate. Four trenches are shown herein, however, the number of trenches can be altered. The trenches are divided into two types. One type of the trenches is disposed in the STIs 14, and are designated as numeral 18. The other type of the trenches is disposed in the active region 16, and are designated as numeral 20. FIG. 1 and subsequent figures show that each STIs 14 has one trench 18 respectively within STIs 14, and two trenches 20 are within the active region 16 as an example. However, the number of the trenches 18 and trenches 20 are not limited to the number in FIG. 1. Trenches 18/20 are usually formed by using a lithography process to form a patterned mask (not shown). Then, the substrate 10 and the STIs 14 are dry etched to form the trenches 18/20 by using the patterned mask as a mask. It is noteworthy that the trenches 18 are formed with a rough surface at the inner sidewall, and the inner bottom. Similarly, the trenches 20 are formed with a rough surface at the inner sidewall 20a and the inner bottom 20b. After etching the substrate 10 to form the trenches 18/20, some residue is left on the substrate 10 and trenches 18/20.

Next, a cleaning process is performed. The cleaning process includes using a first cleaning solution, a second cleaning solution and diluted dydrofluoric acid to clean the substrate 10. The first cleaning solution includes ammonia solution, hydrogen peroxide solution, and deionized water. The second cleaning solution includes hydrochloric acid solution, hydrogen peroxide solution, and deionized water. The cleaning process is performed to remove the native silicon oxide on the substrate 10, the residue on the substrate 10 and trenches 18/20, and some metal ions.

As shown in FIG. 2, a deposition process is performed to form a silicon layer 22 on the inner sidewall and the inner bottom of each of the trenches 18, on the inner sidewall 20a and the inner bottom 20b of each of the trenches 20, and on the mask layer 12. The deposition process can be an atomic layer deposition, a chemical vapor deposition or a physical vapor deposition. According to a preferred embodiment of the present invention, the deposition process can be an atomic layer deposition. The atomic layer deposition can be performed by using the mixture of dichlorosilane and silane to form the silicon layer 22. The atomic layer deposition is performed at a temperature between 500 and 600 degree Celsius, at the pressure of 200 torr and with the flow rate of the dichlorosilane greater than 100 standard cubic centimeters per minute (sccm). The silicon layer 22 formed under this condition is pure silicon, and preferably amorphous pure silicon. According to a preferred embodiment of the present invention, the thickness of the silicon layer 22 is between 5 and 10 angstroms. Because the silicon layer 22 is formed by the atomic layer deposition process, the surface of the silicon layer 22 is smooth. Therefore, the silicon layer 22 can provide a smooth and flat surface for trenches 18/20 by covering the rough surface of trenches 18/20. The trenches 20 will be used to form buried word lines later, therefore, the smooth and flat inner surface is especially important for of the trenches 20.

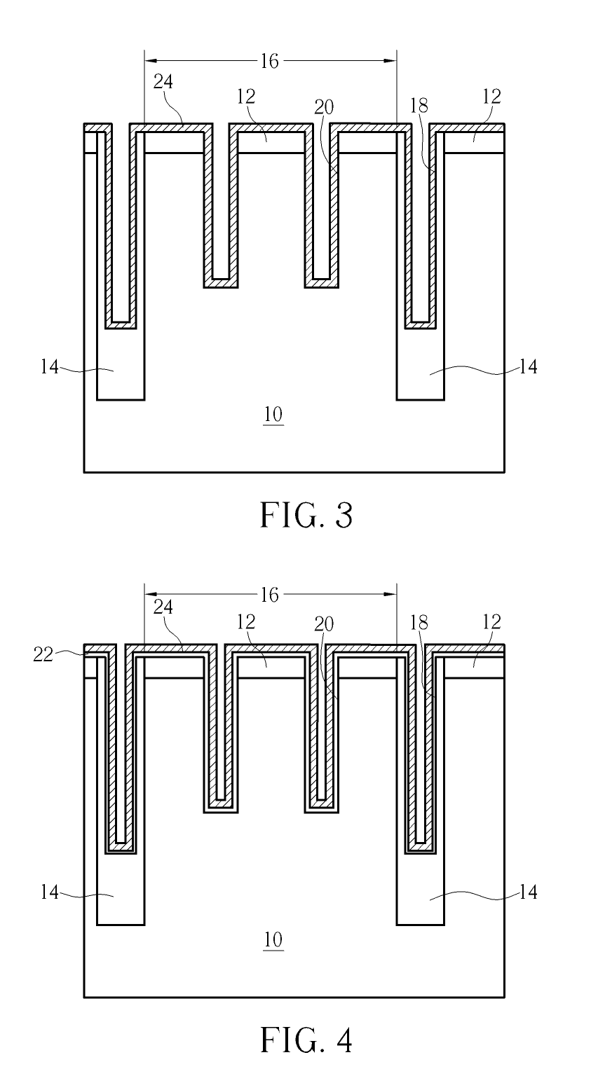

As shown in FIG. 3, after the deposition process, a gate dielectric layer 24 is formed in the trench 18/20, and on the mask layer 12. In this embodiment, the silicon layer 22 is entirely transformed into the gate dielectric layer 24. For example, if the gate dielectric layer 24 is silicon oxide, the gate dielectric layer is formed by an oxidation process such as an in-situ steam generation. During the oxidation process, the entire silicon layer 22 is oxidized to become silicon oxide serving as the gate dielectric layer 24. The gate dielectric layer 24 is not limited to silicon oxide. For example, the gate dielectric layer 24 may be silicon nitride, silicon oxynitride, tantalum oxide, hafnium oxide, nitrogen-containing oxide, hafnium-containing oxide, aluminum-containing oxide, high-k dielectrics or the combination thereof.

According to another preferred embodiment, as shown in FIG. 4, when forming the gate dielectric layer 24, only part of the silicon layer 22 is transformed to the gate dielectric layer 24. In detail, only part of the thickness of the silicon layer 22 becomes gate dielectric layer 24. The difference between FIG. 4 and FIG. 3 is that the silicon layer 22 is FIG. 3 is entirely transformed into the gate dielectric layer 24. The following steps will continue from FIG. 3.

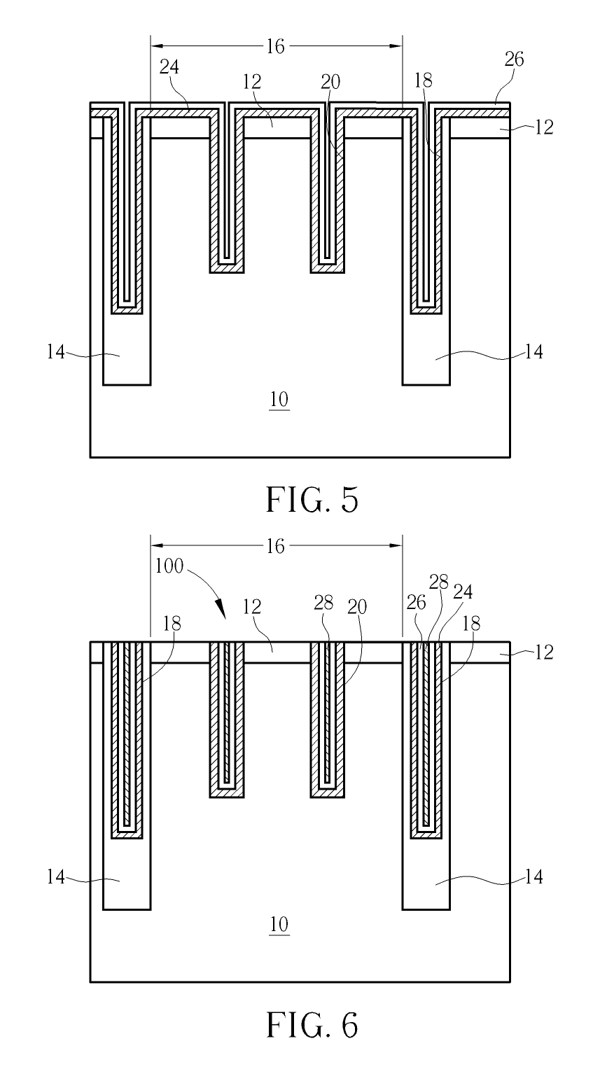

As shown in FIG. 5, a work function layer 26 is formed to conformally cover the gate dielectric layer 24. The work function layer 26 may be titanium nitride, tantalum nitride or other work function materials. As shown in FIG. 6, a conductive layer 28 is formed to fill in each of the trenches 18/20, and cover the mask layer 12. The conductive layer 28 may include one or multiple layers. The conductive layer 28 may be aluminum, tungsten or titanium. Then, a planarization process is performed to remove the gate dielectric layer 24, the work function layer 26 and the conductive layer 28 outside of the trenches 18/20 by taking the mask layer 12 as a stop layer to make the top surface of the gate dielectric layer 24, the work function layer 26 and the conductive layer 28 aligned with the top surface of the mask layer 12. The remaining conductive layer 28 within the active region 16 serves as gates. At this point, a buried word line 100 of the present invention is completed. The buried word line 100 includes trenches 20 in the substrate 10, the gate dielectric layer 24, the work function layer 26 and the conductive layer 28. The feature of the present invention is that the silicon layer 22 is formed to cover the rough surface of the trenches 20 before the gate dielectric layer 24 is formed. Therefore, the gate dielectric layer 24 can be formed on a smooth and flat surface of the silicon layer 22. In this way, the current leakage between the gate dielectric layer 24 and the conductive layer 28 due to the rough surface of the trenches 20 can be prevented.

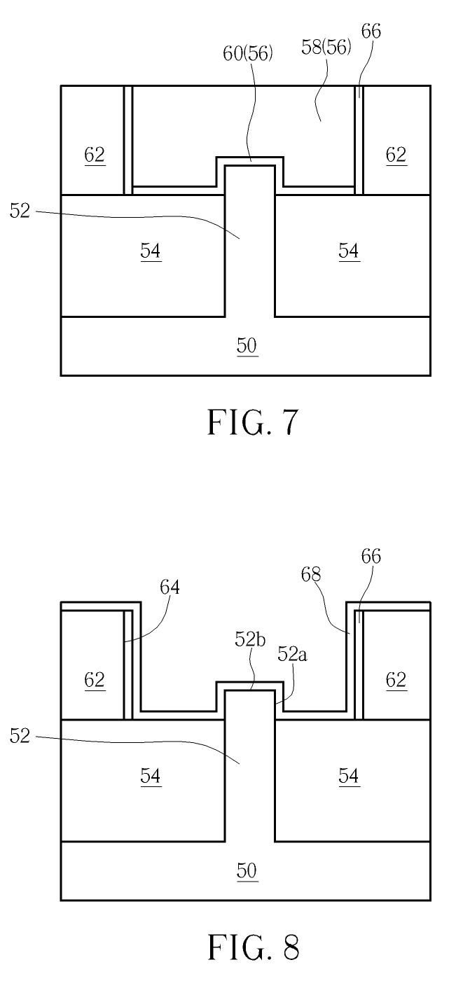

The silicon layer of the present invention can apply to fabricate a gate on a fin structure. FIG. 7 to FIG. 10 depict a method of fabricating a gate on a fin structure according to a second preferred embodiment of the present invention. As shown in FIG. 7, a substrate 50 is provided. A fin structure 52 extends from the substrate 50. In other words, the fin structure 52 protrudes from the substrate 50. Two STIs 54 are disposed at two sides of the fin structure 52, and the STIs 54 sandwich the fin structure 52. The top surface of the STIs 54 is lower than the top surface of the fin structure 52. Therefore, part of the fin structure 52 protrudes from the top surface of the STIs 54. A dummy gate structure 56 crosses and contacts the fin structure 52. The dummy gate structure 56 covers the STIs 54. The dummy gate structure 56 includes a dummy gate 58 and a dummy gate dielectric layer 60. Furthermore, a spacer 66 and an interlayer dielectric 62 surround the dummy gate structure 56. The top surface of the dummy gate structure 56 and the top surface of the interlayer dielectric 62 are aligned.

The substrate 50 may be a silicon substrate, a germanium substrate, a gallium arsenide substrate, a silicon germanium substrate, an indium phosphide substrate, a gallium nitride substrate or a silicon carbide substrate. The material of the fin structure 52 and the material of the substrate 50 are the same. According to a preferred embodiment of the present invention, the substrate 50 in this embodiment is silicon substrate. Therefore, the fin structure 52 is also made of silicon. The dummy gate 58 is preferably polysilicon. The dummy gate dielectric layer 60 may be silicon oxide or silicon nitride.

As shown in FIG. 8, the dummy gate structure 56 is removed to form an opening 64 in the interlayer dielectric 62. Part of the fin structure 52 is exposed from the opening 64. While removing the dummy gate structure 56, the sidewalls 52a and the top plane 52b of the fin structure 52 become rough. Next, a deposition process is performed to forma silicon layer 68 on the surface of the interlayer dielectric 62, the STIs 54, the sidewalls 52a and the top plane 52b. The steps of forming the silicon layer 68 is substantially the same as those disclosed in the first preferred embodiment. The deposition process can be an atomic layer deposition, a chemical vapor deposition or a physical vapor deposition. In this embodiment, the deposition process is preferably an atomic layer deposition. The atomic layer deposition can performed by using the mixture of dichlorosilane, and silane to form silicon layer 68. The atomic layer deposition is performed at a temperature between 500 and 600 degree Celsius, at the pressure of 200 torr and, with the flow rate of the dichlorosilane greater than 100 standard cubic centimeter per minute (sccm). The silicon layer 22 formed under this condition is pure silicon, and preferably amorphous pure silicon. The thickness of the silicon layer 68 is between 5 and 10 angstroms. Because the silicon layer 68 is formed by the atomic layer deposition process, the surface of the silicon layer 68 is smooth. Therefore, the silicon layer 68 can provide a smooth and flat surface for the fin structure 52 by covering the rough surface of the sidewalls 52a and top plane 52b.

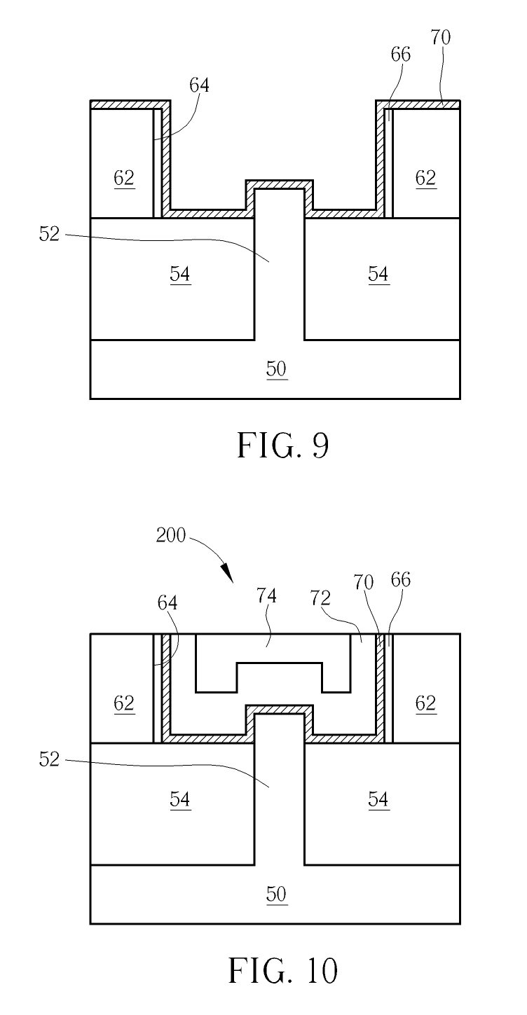

As shown in FIG. 9, after the deposition process, a gate dielectric layer 70 is formed to conformally cover the spacer 66, the fin structure 52 and the interlayer dielectric 62. Similar to the first preferred embodiment, the silicon layer 68 may be entirely transformed into the gate dielectric layer 70 or only part of the thickness of the silicon layer 68 be transformed into the gate dielectric layer 70. FIG. 9 takes the silicon layer 68 entirely transformed into the gate dielectric layer 70 as an example. The gate dielectric layer 70 may be silicon nitride, silicon oxynitride, tantalum oxide, hafnium oxide, nitrogen-containing oxide, hafnium-containing oxide, aluminum-containing oxide, high-k dielectrics or the combination thereof. As shown in FIG. 9, a work function layer 72 is formed to conformally cover the gate dielectric layer 70. The work function layer 72 may be titanium nitride, tantalum nitride or other work function materials. As shown in FIG. 10, a conductive layer 74 is formed to fill in the opening 64 and covers the interlayer dielectric 62. The conductive layer 74 serves as a gate afterwards. The conductive layer 74 may include one or multiple layers. The conductive layer 74 may be aluminum, tungsten or titanium. Then, a planarization process is performed to remove the gate dielectric layer 70, the work function layer 72 and the conductive layer 74 outside of the opening 64. Now, the gate 200 on a fin structure of the present invention is completed. Later, source/drain doping regions (not shown) can be formed in the fin structure 52 at two sides of the conductive layer 74 to form a FinFet.

The silicon layer 68 is formed to cover the rough surface of the fin structure 52 before the gate dielectric layer 70 is formed. Therefore, the gate dielectric layer 70 can be formed on a smooth and flat surface of the silicon layer 68. In this way, the current leakage between the gate dielectric layer 70 and the conductive layer 74 due to the rough surface of the fin structure 52 can be prevented.

Those skilled in the art will readily observe that numerous modifications and alterations of the device and method may be made while retaining the teachings of the invention. Accordingly, the above disclosure should be construed as limited only by the metes and bounds of the appended claims.

1. A method of fabricating a buried word line, comprising:
providing a substrate with a trench therein;
preforming an atomic layer deposition process to form a silicon layer on an inner sidewall and an inner bottom of the trench;
after the atomic layer deposition process, oxidizing the silicon layer to form a gate dielectric layer in the trench; and
forming a conductive layer filling in the trench.

2. The method of fabricating a buried word line of claim 1, wherein the deposition process comprises an atomic layer deposition, a chemical vapor deposition or a physical vapor deposition.

3. The method of fabricating a buried word line of claim 1, wherein after forming the gate dielectric layer, the gate dielectric layer contacts the silicon layer and part of the silicon layer is transformed into the gate dielectric layer.

4. The method of fabricating a buried word line of claim 3, wherein the silicon layer is entirely transformed into the gate dielectric layer.

5. The method of fabricating a buried word line of claim 1, wherein the thickness of the silicon layer is between 5 and 10 angstroms.

6. The method of fabricating a buried word line of claim 1, wherein the silicon layer is silicon.

7. The method of fabricating a buried word line of claim 1, wherein the deposition process is performed at a temperature between 500 and 600 degree Celsius.

8. The method of fabricating a buried word line of claim 1, wherein the gate dielectric layer is made of high-k dielectrics.

9. A fabricating method of a gate on a fin structure, comprising:
providing a substrate, a fin structure extending from the substrate, a dummy gate structure crossing and contacting the fin structure;
removing the dummy gate structure to expose the fin structure;
performing an atomic layer deposition process to form a silicon layer covering a sidewall and a top plane of the fin structure;
after the atomic layer deposition process, oxidizing the silicon layer to form a gate dielectric layer covering the fin structure; and
forming a conductive layer crossing the fin structure.

10. The fabricating method of a gate on a fin structure of claim 9, wherein the deposition process comprises an atomic layer deposition, a chemical vapor deposition or a physical vapor deposition.

11. The fabricating method of a gate on a fin structure of claim 9, wherein when forming the gate dielectric layer, only part of the silicon layer is transformed into the gate dielectric layer.

12. The fabricating method of a gate on a fin structure of claim 9, wherein when forming the gate dielectric layer, the silicon layer is entirely transformed into the gate dielectric layer.

13. The fabricating method of a gate on a fin structure of claim 9, wherein the thickness of the silicon layer is between 5 and 10 angstroms.

14. The fabricating method of a gate on a fin structure of claim 9, wherein the silicon layer is silicon.

15. The fabricating method of a gate on a fin structure of claim 9, wherein the deposition process is performed at a temperature between 500 and 600 degree Celsius.

16. The fabricating method of a gate on a fin structure of claim 9, wherein the gate dielectric layer is made of a high-k dielectric.

17. The method of fabricating a buried word line of claim 1, further comprising an STI embedded in the substrate, wherein the trench is embedded in the STI.
